(19) United States
(12) Patent Application Publication
(10) Pub. No.: US 2024/0324424 A1
(43) Pub. Date: Sep. 26, 2024

(54) DISPLAY DEVICE AND METHOD FOR MANUFACTURING THE SAME

(71) Applicant: Samsung Display Co., Ltd., Yongin-si (KR)

(72) Inventors: SUBIN BAE, Yongin-si (KR); JAEHUN LEE, Yongin-si (KR); YANG-HO JUNG, Yongin-si (KR); TAESUNG KIM, Yongin-si (KR); YUNJONG YEO, Yongin-si (KR)

(21) Appl. No.: 18/429,257

(22) Filed: Jan. 31, 2024

(30) Foreign Application Priority Data
Mar. 23, 2023 (KR) 10-2023-0037731

(51) Int. Cl. H10K 59/80; H10K 59/12

(52) U.S. Cl. CPC H10K 59/8792; H10K 59/1201

(57) ABSTRACT

A display device including a display element layer including a light-emitting element and a pixel-defining film; and a light control layer on the display element layer, and including a first light-blocking portion, a second light-blocking portion spaced apart from the first light-blocking portion in one direction perpendicular to a thickness direction, and a transmission portion between the first light-blocking portion and the second light-blocking portion, wherein the first light-blocking portion includes a first region, and a second region extending from the first region, and crossing the first region, and the second light-blocking portion includes a third region parallel to the first region, and a fourth region extending from the third region in a direction opposite to the second region.

### CROSS-REFERENCE TO RELATED APPLICATION

The present application claims priority to and the benefit of Korean Patent Application No. 10-2023-0037731, filed on Mar. 23, 2023, in the Korean Intellectual Property Office, the content of which in its entirety is herein incorporated by reference.

### BACKGROUND

### 1. Field

Aspects of the present disclosure relate to a display device and a method of manufacturing the same.

### 2. Description of Related Art

As the information society develops, demand for a display device that displays an image is increasing in various forms. For example, a display device may be applied to various electronic devices such as smartphones, digital cameras, laptop computers, navigation systems, and smart televisions. In addition, a display device may also be applied to a center information display (CID) disposed on an instrument panel, a center fascia, or dashboard of a vehicle.

Such a display device may include a configuration for limiting an emission angle of light to improve security or reflection as needed. Research for improving the display quality of display devices including the configuration for limiting an emission angle of light is in progress.

The above information disclosed in this Background section is only for enhancement of understanding of the background of the invention and therefore it may contain information that does not form the prior art.

### SUMMARY

Aspects of the present disclosure are directed to a display device including a light control layer having excellent light transmittance, and a method of manufacturing the same. In some embodiments, the display device includes a light control layer for controlling light having an emission angle equal to or greater than a set or predetermined angle.

According to some embodiments of the present disclosure, there is provided a display device including: a display element layer including a light-emitting element and a pixel-defining film; and a light control layer on the display element layer, and including a first light-blocking portion, a second light-blocking portion spaced apart from the first light-blocking portion in one direction perpendicular to a thickness direction, and a transmission portion between the first light-blocking portion and the second light-blocking portion, wherein the first light-blocking portion includes a first region, and a second region extending from the first region, and crossing the first region, and the second light-blocking portion includes a third region parallel to the first region, and a fourth region extending from the third region in a direction opposite to the second region.

In some embodiments, the first region and the third region each extend in a direction parallel to the thickness direction.

In some embodiments, the light control layer further includes a first pattern portion and a second pattern portion spaced apart from each other with the transmission portion therebetween.

In some embodiments, the first pattern portion is in contact with the first light-blocking portion, and the second pattern portion is in contact with the second light-blocking portion.

In some embodiments, the first pattern portion is on the second region, and the second pattern portion is on the fourth region.

In some embodiments, in the one direction, a width of the first pattern portion is equal to a width of the second pattern portion.

In some embodiments, in the one direction, a width of the second pattern portion is equal to a width of the fourth region.

In some embodiments, the light control layer further includes an auxiliary transmission portion on the first light-blocking portion, the second light-blocking portion, and the transmission portion.

According to some embodiments of the present disclosure, there is provided a method of manufacturing a display device, the method including: preparing a display element layer including a light-emitting element and a pixel-defining film; and forming, on the display element layer, a light control layer including a first light-blocking portion, a second light-blocking portion, and a transmission portion between the first light-blocking portion and the second light-blocking portion, the forming of the light control layer including: forming a preliminary transmission portion having an opening defined therein by providing a first organic material onto the display element layer; forming a preliminary sacrificial film covering the preliminary transmission portion; forming a plurality of sacrificial films by removing, from the preliminary sacrificial film, a first portion extending in a first direction crossing a thickness direction; forming a transmission portion from the preliminary transmission portion by filling the opening with a second organic material; and removing the sacrificial films, and forming the first light-blocking portion and the second light-blocking portion that fill regions in which the sacrificial films are removed.

In some embodiments, the method further includes, between the forming of a preliminary sacrificial film and the forming of a plurality of sacrificial films: forming a preliminary pattern portion on the preliminary sacrificial films; and forming a pattern portion by removing, from the preliminary pattern portion, a second portion extending in the first direction.

In some embodiments, the preliminary pattern portion entirely overlaps the preliminary sacrificial film.

In some embodiments, the preliminary sacrificial film is formed by depositing metal.

In some embodiments, in the forming of the plurality of sacrificial films, the first portion is removed by anisotropic etching.

In some embodiments, the sacrificial films are formed on a side surface of the preliminary transmission portion defining the opening.

In some embodiments, in the forming of the first light-blocking portion and the second light-blocking portion, the sacrificial films are removed by wet etching.

In some embodiments, the forming of the transmission portion includes: forming a first preliminary transmission region and a second preliminary transmission region by providing the first organic material; and forming the transmission portion by removing the second preliminary transmission region, wherein the first preliminary transmission region is formed by filling the opening, and wherein the second preliminary transmission region is formed on the preliminary transmission portions and the first preliminary transmission region.

In some embodiments, the second preliminary transmission region is removed by an ashing process.

In some embodiments, the method further includes, after the forming of the first light-blocking portion and the second light-blocking portion: forming an auxiliary transmission portion on the first light-blocking portion, the second light-blocking portion, and the transmission portion.

In some embodiments, the forming of the preliminary transmission portion includes: providing the first organic material on the display element layer; and forming the preliminary transmission portions by patterning the first organic material using a hard mask.

In some embodiments, in the removing of the first portion, the hard mask is removed.

Other aspects, features, and characteristics that are not described above will be more clearly understood from the accompanying drawings, claims, and detailed description.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a perspective view of a display device according to some embodiments of the present disclosure;

FIG. 2 is a cross-sectional view illustrating a part taken along the line I-I′ in FIG. 1, according to some embodiments of the present disclosure;

FIG. 3 is a plan view illustrating a part of a display device according to some embodiments of the present disclosure;

FIG. 4 is a cross-sectional view illustrating a part taken along the line II-II′ in FIG. 3, according to some embodiments of the present disclosure;

FIG. 5 is an enlarged cross-sectional view of the region AA′ in FIG. 4, according to some embodiments of the present disclosure;

FIG. 6 is a cross-sectional view illustrating a display device according to some embodiments of the present disclosure;

FIG. 7 is a cross-sectional view illustrating a display device according to some embodiments of the present disclosure;

FIG. 8 is a diagram illustrating a vehicle in which a display device according to according to some embodiments of the present disclosure is disposed;

FIG. 9A is a flowchart illustrating a method of manufacturing a display device according to some embodiments of the present disclosure;

FIG. 9B is a flowchart illustrating a method of manufacturing a display device according to some embodiments of the present disclosure;

FIG. 10 is a diagram schematically illustrating an operation of a method of manufacturing a display device according to some embodiments of the present disclosure;

FIG. 11 is a diagram schematically illustrating an operation of a method of manufacturing a display device according to some embodiments of the present disclosure;

FIG. 12 is a diagram schematically illustrating an operation of a method of manufacturing a display device according to some embodiments of the present disclosure;

FIG. 13 is a diagram schematically illustrating an operation of a method of manufacturing a display device according to some embodiments of the present disclosure;

FIG. 14 is a diagram schematically illustrating an operation of a method of manufacturing a display device according to some embodiments of the present disclosure;

FIG. 15 is a diagram schematically illustrating an operation of a method of manufacturing a display device according to some embodiments of the present disclosure;

FIG. 16 is a diagram schematically illustrating an operation of a method of manufacturing a display device according to some embodiments of the present disclosure;

FIG. 17 is a diagram schematically illustrating an operation of a method of manufacturing a display device according to some embodiments of the present disclosure;

FIG. 18 is a diagram schematically illustrating an operation of a method of manufacturing a display device according to some embodiments of the present disclosure;

FIG. 19 is a diagram schematically illustrating an operation of a method of manufacturing a display device according to some embodiments of the present disclosure;

FIG. 20 is a diagram schematically illustrating an operation of a method of manufacturing a display device according to some embodiments of the present disclosure; and

FIG. 21 is a diagram schematically illustrating an operation of a method of manufacturing a display device according to some embodiments of the present disclosure.

### DETAILED DESCRIPTION

The attached drawings for illustrating exemplary embodiments of the inventive concept are referred to in order to gain a sufficient understanding of the inventive concept, the merits thereof, and the objectives accomplished by the implementation of the inventive concept. The inventive concept may, however, be embodied in many different forms and should not be construed as being limited to the exemplary embodiments set forth herein; rather, these exemplary embodiments are provided so that this disclosure will be thorough and complete, and will fully convey the concept of the invention to those skilled in the art.

Hereinafter, the present invention will be described in detail by explaining exemplary embodiments of the inventive concept with reference to the attached drawings. Like reference numerals in the drawings denote like elements, and their descriptions may not be provided. Sizes of components in the drawings may be exaggerated for convenience of explanation. In other words, because sizes and thicknesses of components in the drawings are arbitrarily illustrated for convenience of explanation, the following exemplary embodiments are not limited thereto.

Unless otherwise defined, all terms (including technical and scientific terms) used in this specification have the same meaning as commonly understood by one of ordinary skill in the art to which this invention belongs. In addition, terms such as terms defined in commonly used dictionaries should be interpreted as having a meaning consistent with the meaning having in the context of the related technology, and should not be interpreted as too ideal or too formal unless explicitly defined here.

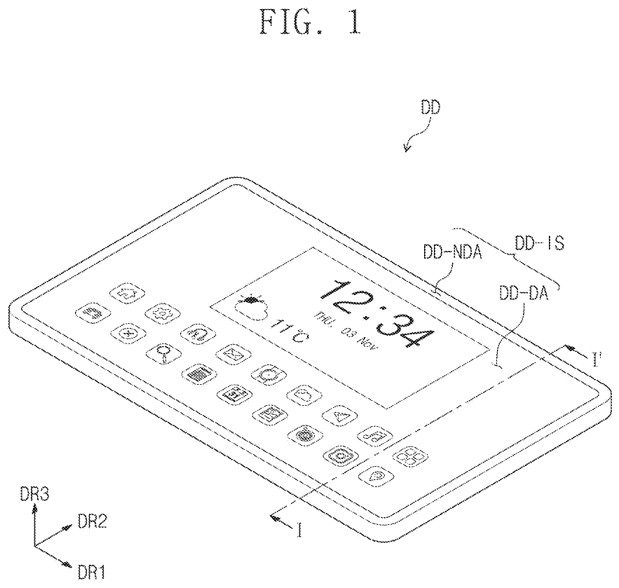

Hereinafter, a display according to some embodiments of the present disclosure will be described with reference to the accompanying drawings. FIG. 1 is a perspective view illustrating a display device according to some embodiments of the present disclosure.

Referring to FIG. 1, a display device DD according to some embodiments is a device activated in response to an electrical signal. For example, the display device DD may be a device such as a television, a monitor, a billboard, a tablet computer, a car navigation unit, a personal computer, a laptop computer, a private digital terminal, a game console, a smartphone, and a camera. However, these are merely presented as examples, and other electronic devices may also be employed without departing from the scope of the present disclosure.

The display device DD may display an image IM through a display surface DD-IS. The display surface DD-IS may be parallel to a plane defined by a first direction DR1 and a second direction DR2. FIG. 1 illustrates the display device DD provided with a flat display surface DD-IS; however, embodiments of the present disclosure are not limited thereto. The display device DD may include a curved display surface or a three-dimensional display surface. The three-dimensional display surface may include a plurality of display regions respectively indicating directions different from each other.

The display surface DD-IS may include a display region DD-DA and a non-display region DD-NDA. The display device DD may display the image IM through the display region DD-DA. The non-display region DD-NDA may be adjacent to the display region DD-DA. The non-display region DD-NDA may surround the display region DD-DA. However, FIG. 1 illustrates an example, and the non-display region DD-NDA may be disposed adjacent to only one side of the display region DD-DA, or may be omitted, as may be desired.

FIG. 1 and the following drawings illustrate first to third directional axes DR1, DR2, and DR3, and directions indicated by the first to third directional axes DR1, DR2, and DR3 described herein are relative concepts, and may thus be changed to other directions. In addition, the directions indicated by the first to third directional axes DR1, DR2, and DR3 may be described as the first to third directions, and thus be denoted as the same reference numerals or symbols. In the present disclosure, the first directional axis DR1 and the second directional axis DR2 may be orthogonal to each other, and the third directional axis DR3 may indicate a normal direction of a plane defined by the first direction DR1 and the second direction DR2.

A thickness direction of the display device DD may be a direction parallel to the third directional axis DR3. An upper side (or upper surface) and a lower side (or lower surface) may be defined on the basis of the third directional axis DR3. The upper side (or upper surface) means a side in a direction (or surface) getting closer to the display surface DD-IS, and the lower side (or lower surface) means a side in a direction (or surface) getting farther away from the display surface DD-IS. A cross-section means a surface parallel to the thickness direction DR3. A plane means a surface orthogonal to the thickness direction DR3. The plane may be defined by the first directional axis DR1 and the second directional axis DR2.

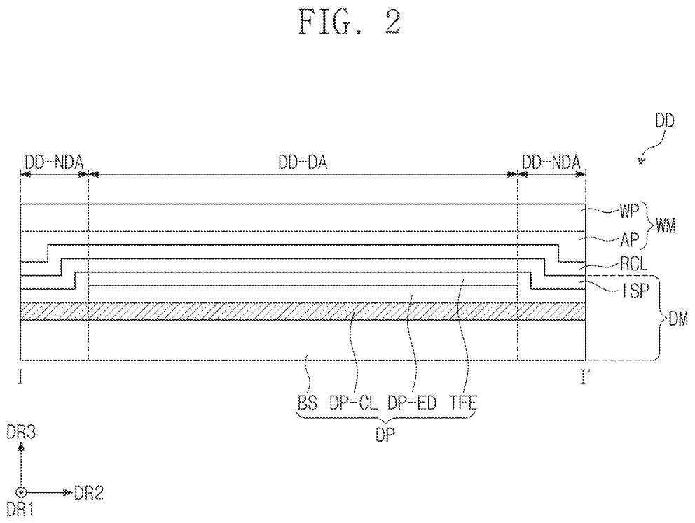

FIG. 2 is a cross-sectional view illustrating a part taken along the line I-I′ in FIG. 1, according to some embodiments of the present disclosure. FIG. 2 may be a cross-sectional view illustrating the display device DD.

Referring to FIG. 2, the display device DD may include a display module DM, a light control layer RCL disposed on the display module DM, and a window member WM disposed on the light control layer RCL. The display module DM may include a display panel DP, and an input-sensing layer ISP disposed on the display panel DP.

The display panel DP may have a configuration for substantially generating an image. The display panel DP may be a light-emitting display panel, and for example, the display panel DP may be an organic light-emitting display panel, an inorganic light-emitting display panel, a quantum dot display panel, a micro-LED display panel, or a nano-LED display panel. The display panel DP may be referred to as a display layer. The display panel DP may include a base layer BS, a circuit layer DP-CL, a display element layer DP-ED, and an encapsulation layer TFE which are sequentially stacked (e.g., stacked on one another in the enumerated order).

The base layer BS may be a member that provides a base surface on which the circuit layer DP-CL is disposed. The base layer BS may be a rigid substrate, or a flexible substrate which is capable of bending, folding, or rolling. The base layer BS may be a glass substrate, a metal substrate, or a polymer substrate. However, embodiments of the present disclosure are not limited thereto, and the base layer BS may be an inorganic layer, an organic layer, or a composite material layer.

The circuit layer DP-CL may be disposed on the base layer BS. The circuit layer DP-CL may include an insulating layer, a semiconductor pattern, a conductive pattern, and a signal line. After an insulating layer, a semiconductor layer, and a conductive layer are formed on the base layer BS by coating, deposition, or the like, the insulating layer, the semiconductor layer, and the conductive layer may be selectively patterned by performing a photolithography process multiple times. Thereafter, a semiconductor pattern, a conductive pattern, and a signal line included in the circuit layer DP-CL may be formed.

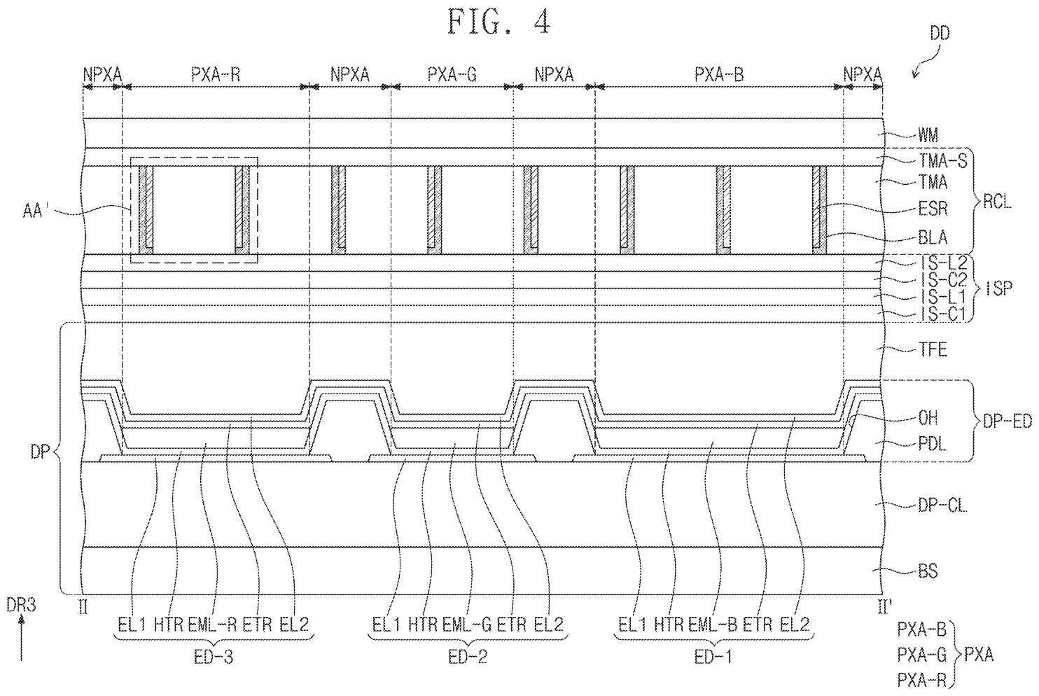

The display element layer DP-ED may be disposed on the circuit layer DP-CL. The display element layer DP-ED may include light-emitting elements ED-1, ED-2, and ED-3 (see, e.g., FIG. 4). For example, the display element layer DP-ED may include an organic light-emitting material, an inorganic light-emitting material, an organic-inorganic light-emitting material, quantum dots quantum rods, a micro-LED, or a nano-LED.

The encapsulation layer TFE may be disposed on the display element layer DP-ED. The encapsulation layer TFE may protect the display element layer DP-ED from moisture, oxygen, and foreign matters such as dust particles.

The input-sensing layer ISP may be disposed on the display panel DP. The input-sensing layer ISP may sense an external input to change the external input into a set or predetermined input signal, and may provide the input signal to the display panel DP. For example, the input-sensing layer ISP in the display device DD according to some embodiments is a touch-sensing part that senses a touch. The input-sensing layer ISP may recognize a user's direct touch, a user's indirect touch, an object's direct touch, an object's indirect touch, or the like.

The input-sensing layer ISP may sense at least any one of a position and a strength (pressure) of a touch applied from the outside. The display panel DP may receive the input signal from the input-sensing layer ISP, and may generate an image corresponding to the input signal. For example, the input-sensing layer ISP may capacitively sense an external input. However, this is merely an example, and a driving method for the input-sensing layer ISP is not limited to any one embodiment.

The input-sensing layer ISP may be formed on the display panel DP through a continuous process. In this case, the input-sensing layer ISP may be directly disposed on the display panel DP. That is, a separate adhesive member may not be disposed between the input-sensing layer ISP and the display panel DP. In some examples, the input-sensing layer ISP may be bonded to the display panel DP through an adhesive member. The adhesive member may include a typical bonding agent or adhesive.

In this disclosure, the wording, “one component is directly disposed on another component” means “no third component is disposed between the one component and the other component”. That is, another component being “directly disposed” on one component means that the one component and the other component are in “contact” with each other.

The light control layer RCL may limit an emission angle of light emitted from the display panel DP. The light control layer RCL may absorb light travelling at an angle exceeding a set or predetermined angle range, and may transmit only light travelling at an angle within the set or predetermined angle range. For example, the light control layer RCL may be a light control film (LCF) applied to a display device for vehicles. The light control film (LCF) may prevent light emitted by the display device DD from being reflected on a windshield of a vehicle and obstructing driver's visual field, or substantially reducing instances thereof. In addition, the light control layer RCL may be a component provided to protect user's personal privacy so that the image IM is invisible to other people located around a user of the display device DD.

According to some embodiments, the light control layer RCL includes a light-blocking portion BLA (see, e.g., FIG. 4) and a transmission portion TMA (see, e.g., FIG. 4). The light control layer RCL is manufactured through a method of manufacturing a display device according to some embodiments including an operation of forming a light control layer, and therefore the light control layer RCL may include the transmission portion TMA (see, e.g., FIG. 4) having a relatively great width (e.g., large width) and the light-blocking portion BLA (see, e.g., FIG. 4) having a relatively small width. At this time, the width refers to the width in one direction perpendicular to the thickness direction DR3. Accordingly, the light control layer RCL according to some embodiments shows excellent light transmittance, and the display device DD including the light control layer RCL may exhibit excellent display quality. The light control layer RCL and the method of manufacturing a display device according to some embodiments will be described later in more detail.

The window member WM may be disposed on the display module DM. The window member WM may include a window WP and an adhesive layer AP. The window member WM may further include at least one functional layer provided on the window WP. For example, the functional layer may be a hard-coating layer, an anti-fingerprint coating layer, or the like; however, embodiments of the present disclosure are not limited thereto.

The window WP may include an optically transparent insulating material. The window WP may be a glass substrate, or a polymer substrate. For example, the window WP may be a reinforced glass substrate which has been subjected to a reinforcing treatment. In some examples, the window WP may be made from polyimide, polyacrylate, polymethylmethacrylate, polycarbonate, polyethylenenaphthalate, polyvinylidene chloride, polyvinylidene difluoride, polystyrene, ethylene vinylalcohol copolymer, or a combination thereof. However, this is merely an example, and a material included by the window WP is not limited thereto.

The window WP and the display module DM may be bonded via the adhesive layer AP. The adhesive layer AP may include a typical bonding agent such as pressure sensitive adhesive (PSA), optically clear adhesive (OCA), or an optically clear resin (OCR); however, embodiments of the present disclosure are not limited thereto. Unlike what is illustrated, the adhesive layer AP may be omitted.

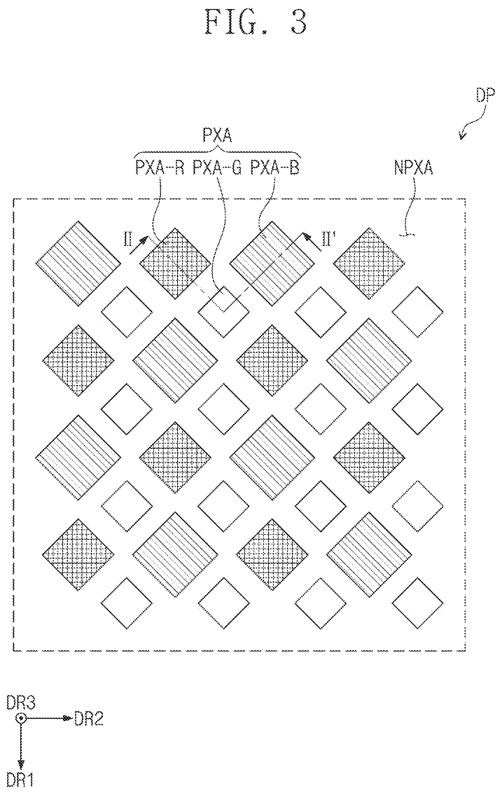

FIG. 3 is an enlarged plan view of the display panel DP. The display panel DP may be divided into a light-emitting region PXA and a non-light-emitting region NPXA. The non-light-emitting region NPXA may surround the light-emitting region PXA.

The light-emitting region PXA may be provided as a plurality of light-emitting regions that emit light having different wavelength regions. The light-emitting region PXA may include a blue light-emitting region PXA-B, a green light-emitting region PXA-G, and a red light-emitting region PXA-R. However, embodiments of the present disclosure are not limited thereto, and the light-emitting regions PXA-R, PXA-G, and PXA-B may emit light having colors other than red light, green light, and blue light.

In the light-emitting region PXA, the blue light-emitting region PXA-B may have the greatest area, and the green light-emitting region PXA-G may have the smallest area. At this time, the area may refer to an area on a plane. However, this is merely an example, and areas of the blue light-emitting region PXA-B, the green light-emitting region PXA-G, and the red light-emitting region PXA-R are not limited thereto.

FIG. 3 illustrates that the red light-emitting region PXA-R and the blue light-emitting region PXA-B are alternately arranged in a first row along the second direction DR2, and the green light-emitting region PXA-G is arranged in a second row while being spaced apart from (e.g., separated/offset from) the red light-emitting region PXA-R and the blue light-emitting region PXA-B. However, this is merely an example, and the arrangement of the red light-emitting region PXA-R, the green light-emitting region PXA-G, and the blue light-emitting region PXA-B is not limited thereto. In addition, the planar shapes of the red light-emitting region PXA-R, the green light-emitting region PXA-G, and the blue light-emitting region PXA-B are not limited to what is illustrated, and may be defined in a shape different from what is illustrated.

FIG. 4 is a cross-sectional view illustrating a part taken along the line II-II′ in FIG. 3, according to some embodiments of the present disclosure. FIG. 4 may be a cross-sectional view specifically illustrating the display panel DP.

The base layer BS may include a single-layered or a multilayered structure. For example, the base layer BS may include a first synthetic resin layer, a single- or multi-layered intermediate layer, and a second synthetic resin layer, which are sequentially stacked. The intermediate layer may be referred to as a base barrier layer. The intermediate layer may include a silicon oxide (SiOₓ) layer, and an amorphous silicon (a-Si) layer disposed on the silicon oxide (SiOₓ) layer; however, embodiments of the present disclosure are not limited thereto. For example, the intermediate layer may include at least one of a silicon oxide layer, a silicon nitride layer, a silicon oxynitride layer, an amorphous silicon layer, and/or the like.

The first and second synthetic resin layers may each include a polyimide-based resin. In addition, the first and second synthetic resin layers may each include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, a perylene-based resin, and/or the like. In this disclosure, “˜˜”-based resin means a resin including a “˜˜” functional group.

The circuit layer DP-CL may include a plurality of transistors. The transistors may each include a control electrode, an input electrode, and an output electrode. For example, the circuit layer DP-CL may include a switching transistor and a driving transistor for driving light-emitting elements ED-1, ED-2, and ED-3 of the display element layer DP-ED.

The display element layer DP-ED may include the light-emitting elements ED-1, ED-2, and ED-3 and a pixel-defining film PDL. Pixel openings OH may be defined in the pixel-defining film PDL. For example, the pixel-defining film PDL may include an organic light-blocking material or an inorganic light-blocking material including a black pigment or black dye. The light-emitting regions PXA-R, PXA-G, and PXA-B may be regions respectively separated by the pixel-defining film PDL. The non-light-emitting region NPXA may be regions between the light-emitting regions PXA-R, PXA-G, and PXA-B that are adjacent to each other (e.g., nearest to one another), and may be regions corresponding to the pixel-defining film PDL.

The light-emitting regions PXA-R, PXA-G, and PXA-B may respectively correspond to pixels. The pixel-defining film PDL may separate the first to third light-emitting elements ED-1, ED-2, and ED-3. Light-emitting layers EML-B, EML-G, and EML-R of the first to third light-emitting elements ED-1, ED-2, and ED-3 may be disposed and separated in the pixel openings OH defined in the pixel-defining film PDL.

The display element layer DP-ED may include the first to third light-emitting elements ED-1, ED-2, and ED-3. The first to third light-emitting elements ED-1, ED-2, and ED-3 may be spaced apart from (e.g., separated/offset from) each other in one direction perpendicular to the thickness direction DR3. The first to third light-emitting element ED-1, ED-2, or ED-3 may include a first electrode EL1, a second electrode EL2 disposed on the first electrode EL1, and the light-emitting layers EML-B, EML-G, or EML-R disposed between the first electrode EL1 and the second electrode EL2. In addition, the first to third light-emitting elements ED-1, ED-2, or ED-3 may include a hole transport region HTR disposed between the first electrode EL1 and the light-emitting layer EML-B, EML-G, or EML-R, and an electron transport region ETR disposed between the light-emitting layer EML-B, EML-G, or EML-R and the second electrode EL2.

The first to third light-emitting elements ED-1, ED-2, and ED-3 may respectively emit light having different wavelength regions. The first light-emitting element ED-1 may include a first light-emitting layer EML-B that emits first light. The second light-emitting element ED-2 may include a second light-emitting layer EML-G that emits second light different from the first light. The third light-emitting element ED-3 may include a third light-emitting layer EML-R that emits third light different from the first light and the second light. The first light may be blue light, the second light may be green light, and the third light may be red light. The blue light-emitting region PXA-B, the green light-emitting region PXA-G, and the red light-emitting region PXA-R may respectively correspond to the first light-emitting element ED-1, the second light-emitting element ED-2, and the third light-emitting element ED-3. However, embodiments of the present disclosure are not limited thereto, and the first to third light-emitting elements ED-1, ED-2, and ED-3 may emit light having the same wavelength region, or may emit light having wavelength regions of which at least one is different from the rest. For example, the first to third light-emitting elements ED-1, ED-2, and ED-3 may all emit blue light or white light.

The first electrode EL1 may be at least partially exposed in the pixel opening OH. The first electrode EL1 may be formed of a metal material, a metal alloy, or a conductive compound. The first electrode EL1 may be an anode or a cathode. The first electrode EL1 may be a pixel electrode. The first electrode EL1 may be a transmissive electrode, a semi-transmissive electrode, or a reflective electrode.

The hole transport region HTR may be formed of a known hole injection material and/or a known hole transport material. The hole transport region HTR may include at least one of a hole injection layer, a hole transport layer, or an electron blocking layer. The hole transport region HTR may entirely overlap (e.g., overlap in a plan view) the light-emitting regions PXA-R, PXA-G, and PXA-B, and the non-light-emitting region NPXA. That is, the hole transport regions HTR may be provided as a common layer so as to overlap (e.g., in a plan view) the light-emitting regions PXA-R, PXA-G, and PXA-B and the non-light-emitting region NPXA. However, embodiments of the present disclosure are not limited thereto, and the hole transport regions HTR may be patterned and provided such that the hole transport regions HTR is divided into sections respectively corresponding to the light-emitting regions PXA-R, PXA-G, and PXA-B.

The first to third light-emitting layers EML-B, EML-G, and EML-R may each include an organic light-emitting material or an inorganic light-emitting material. For example, the first to third light-emitting layers EML-B, EML-G, and EML-R may each include a fluorescent light-emitting or phosphorescent light-emitting material. The first to third light-emitting layers EML-B, EML-G, and EML-R may each include quantum dots as a light-emitting material.

The electron transport region ETR may be formed of a known electron injection material and/or a known electron transport material. The electron transport region ETR may include at least one of an electron injection layer, an electron transport layer, or a hole blocking layer. The electron transport region ETR may entirely overlap (e.g., entirely overlap in a plan view) the light-emitting regions PXA-R, PXA-G, and PXA-B and the non-light-emitting region NPXA. That is, the electron transport region ETR may be provided as a common layer to overlap (e.g., overlap in a plan view) the light-emitting regions PXA-R, PXA-G, and PXA-B and the non-light-emitting region NPXA. However, embodiments of the present disclosure are not limited thereto, and the electron transport regions ETR may be patterned and provided such that the electron transport region ETR is divided into sections respectively corresponding to the light-emitting regions PXA-R, PXA-G, and PXA-B.

The second electrode EL2 may be a common electrode. The second electrode EL2 may be a cathode or an anode; however, embodiments of the present disclosure are not limited thereto. For example, when the first electrode EL1 is an anode, the second electrode EL2 may be a cathode; and when the first electrode EL1 is a cathode, the second electrode EL2 may be an anode. The second electrode EL2 may be a transmissive electrode, a semi-transmissive electrode, or a reflective electrode. When the second electrode EL2 is a transmissive electrode, the second electrode EL2 may be composed of transparent metal oxide, for example, indium-tin oxide (ITO), indium-zinc oxide (IZO), zinc oxide (ZnO), indium-tin-zinc oxide (ITZO), or the like.

The encapsulation layer TFE may be disposed on the display element layer DP-ED. The encapsulation layer TFE may include at least one inorganic film (hereinafter, inorganic encapsulation film). In addition, the encapsulation layer TFE may include at least one organic film (hereinafter, organic encapsulation film), and at least one inorganic encapsulation film.

The inorganic encapsulation film may protect the display element layer DP-ED from moisture/oxygen, and the organic encapsulation film may protect the display element layer DP-ED from foreign matters such as dust particles. The inorganic encapsulation film may include silicon nitride, silicon oxynitride, silicon oxide, titanium oxide, aluminum oxide, and/or the like, but is not specially limited thereto. The organic encapsulation film may include an acrylate-based compound, an epoxy-based compound, and/or the like. The organic encapsulation film may include a photopolymerizable organic material, but is not specially limited thereto.

The input-sensing layer ISP may include a first conductive layer IS-C1, a first insulating layer IS-L1 disposed on the first conductive layer IS-C1, a second conductive layer IS-C2 disposed on the first insulating layer IS-L1, and a second insulating layer IS-L2 disposed on the second conductive layer IS-C2. The input-sensing layer ISP may further include a base insulating layer disposed under the first conductive layer IS-C1.

The first insulating layer IS-L1 and the second insulating layer IS-L2 may each include a single layer or a plurality of layers. The first insulating layer IS-L1 and the second insulating layer IS-L2 may each include an organic material or an inorganic material. The first insulating layer IS-L1 and the second insulating layer IS-L2 may each include at least one of silicon nitride, silicon oxynitride, or silicon oxide. In some examples, the first insulating layer IS-L1 and the second insulating layer IS-L2 may each include an epoxy-based resin, an acrylate-based resin, an imide-based resin, and/or the like.

The first conductive layer IS-C1 and the second conductive layer IS-C2 may each include a single layer or a plurality of layers. The first conductive layer IS-C1 and the second conductive layer IS-C2 may each include, as a single-layer, a metal layer or a transparent conductive layer. The metal layer may include molybdenum (Mo), silver (Ag), titanium (Ti), copper (Cu), aluminum (AI), or an alloy thereof. The transparent conductive layer may include a transparent conductive oxide such as indium-tin oxide (ITO), indium-zinc oxide (IZO), indium-tin-zinc oxide (ITZO), or the like. In addition, the transparent conductive layer may include a conductive polymer such as PEDOT, metal nanowires, graphene, or the like.

The first conductive layer IS-C1 and the second conductive layer IS-C2 may each have a three-layered structure such as ITO/Ag/ITO. In addition, the first conductive layer IS-C1 and the second conductive layer IS-C2 may each include at least one metal layer and at least one transparent conductive layer.

The light control layer RCL may be disposed on the input-sensing layer ISP. The light control layer RCL may be formed on the input-sensing layer ISP through a continuous process. In this case, the light control layer RCL may be directly disposed on the input-sensing layer ISP.

The light control layer RCL may include a light-blocking portion BLA and a transmission portion TMA. The light-blocking portion BLA may be formed by adopting, without any limitation, light-absorbing materials. For example, a dark colored pigment such as a black pigment or a grey pigment, a dark colored dye, a metal such as aluminum or silver, a metal oxide, a dark colored polymer, or the like may be used as the light-absorbing material.

The transmission portion TMA may include an optically transparent organic material. For example, the transmission portion TMA may include at least one of a polyimide-based resin, an acrylate-based resin, a siloxane-based resin, and/or the like. However, this is merely an example, and a material constituting the transmission portion TMA is not limited thereto.

Referring to FIG. 4, a plurality of the light-blocking portions BLA may be provided. FIG. 4 illustrates that among eight light-blocking portions BLA, six light-blocking portions BLA are disposed in the light-emitting region PXA, and two light-blocking portions BLA are disposed in the non-light-emitting region NPXA. It is illustrated that among the six light-blocking portions BLA, three light-blocking portions BLA are disposed in the blue light-emitting region PXA-B, two light-blocking portions BLA are disposed in the red light-emitting region PXA-R, and one light-blocking portion BLA is disposed in the green light-emitting region PXA-G. However, this is merely an example, and the arrangement and number of the light-blocking portions BLA are not limited thereto. For example, the light-blocking portions BLA may be disposed overlapping (e.g., in a plan view) the light-emitting region PXA, and not overlapping the non-light-emitting region NPXA. In addition, the number of the light-blocking portions BLA disposed in each of the blue light-emitting region PXA-B, the green light-emitting region PXA-G, and the blue light-emitting region PXA-B is not limited to any one embodiment. In this disclosure, the wording, “one component overlaps another component” is not limited to a case that the one component and the other component have the same area and shape, and includes a case that they have different areas and/or different shapes.

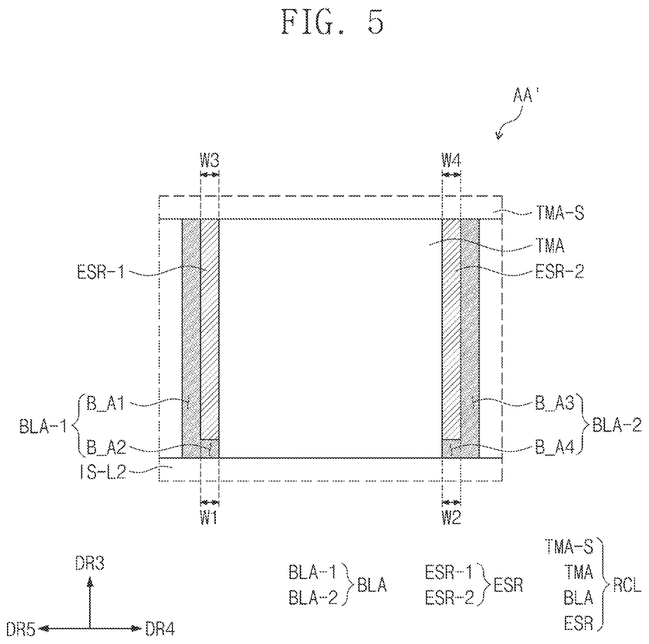

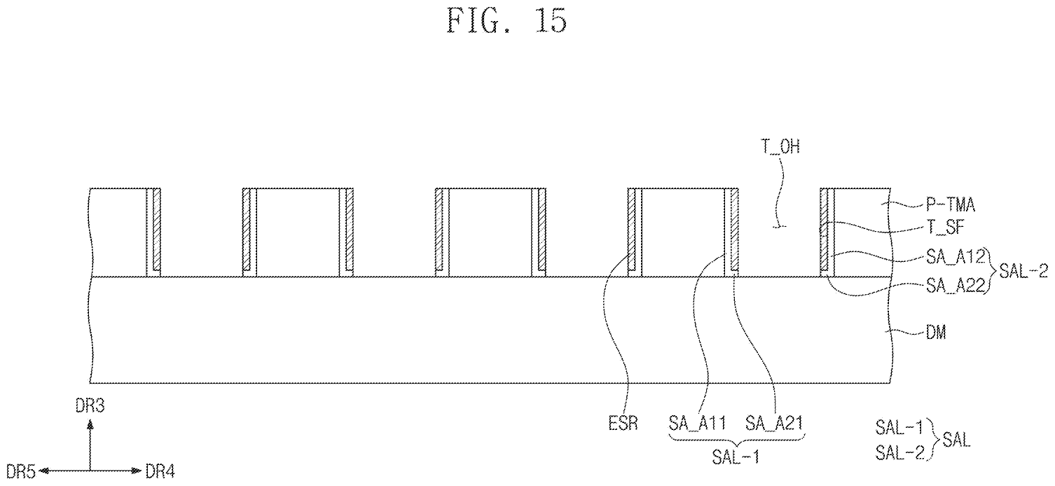

The light control layer RCL may further include a pattern portion ESR. The pattern portion ESR may be formed of an organic material, an inorganic material, or a metal. In the thickness direction DR3, the pattern portion ESR may be disposed on one region B_A2 and B_A4 (see, e.g., FIG. 5) of the light-blocking portion BLA. The one region B_A2 and B_A4 (see, e.g., FIG. 5) of the light-blocking portion BLA may be a region extending in a direction perpendicular to the thickness direction DR3. In a method of manufacturing a display device according to some embodiments to be described later, the pattern portion ESR may be formed from an etch stopper. The pattern portion ESR may be formed to prevent or substantially reduce damage to a sacrificial film SAL (see, e.g., FIG. 15) in the method of manufacturing a display device according to some embodiments.

The light control layer RCL may further include an auxiliary transmission portion TMA-S. The auxiliary transmission portion TMA-S may be formed of the same or substantially the same material as the transmission portion TMA. The auxiliary transmission portion TMA-S and the transmission portion TMA may have an integrated shape. The auxiliary transmission portion TMA-S may be disposed on the light-blocking portion BLA, the pattern portion ESR, and the transmission portion TMA. The auxiliary transmission portion TMA-S may define an upper surface of the light control layer RCL. The auxiliary transmission portion TMA-S may be a planarization layer. A window member WM may be disposed on the auxiliary transmission portion TMA-S.

FIG. 5 is an enlarged cross-sectional view of the region AA′ in FIG. 4, according to some embodiments of the present disclosure. Referring to FIG. 5, the light-blocking portion BLA may include a first light-blocking portion BLA-1 and a second light-blocking portion BLA-2 spaced apart from (e.g., separated/offset from) each other in a fourth direction DR4 perpendicular to the thickness direction DR3. The transmission portion TMA may be disposed between the first light-blocking portion BLA-1 and the second light-blocking portion BLA-2. In FIG. 5, the fourth direction DR4 and a fifth direction DR5 each perpendicular to the thickness direction DR3 are illustrated. The fourth direction DR4 is defined as a direction opposite to the fifth direction DR5. The fourth direction DR4 and the fifth direction DR5 may be parallel to a plane defined by the first direction DR1 (see, e.g., FIG. 1) and the second direction DR2 (see, e.g., FIG. 1).

The first light-blocking portion BLA-1 may include a first region B_A1 and a second region B_A2 crossing the first region B_A1. The second region B_A2 may extend from the first region B_A1. The first region B_A1 may extend in a direction parallel to the thickness direction DR3, and the second region B_A2 may extend in the fourth direction DR4.

The second light-blocking portion BLA-2 may include a third region B_A3 and a fourth region B_A4 crossing the third region B_A3. The fourth region B_A4 may extend from the third region B_A3. The third region B_A3 may extend in a direction parallel to the thickness direction DR3, and the fourth region B_A4 may extend in the fifth direction DR5.

Referring to FIG. 5, the second region B_A2 of the first light-blocking portion BLA-1 and the fourth region B_A4 of the second light-blocking portion BLA-2 may extend in a direction getting closer to each other. In some examples, referring to FIGS. 4 and 5, in any two light-blocking portions BLA spaced apart from (e.g., separated/offset from) each other with the transmission portion TMA therebetween, the second region B_A2 and the fourth region B_A4 may extend in a direction away from each other. In this case, unlike what is illustrated in FIG. 5, the second region B_A2 of the first light-blocking portion BLA-1 may extend in the fifth direction DR5, and the fourth region B_A4 of the second light-blocking portion BLA-2 may extend in the fourth direction DR4.

The pattern portion ESR may include a first pattern portion ESR-1 and a second pattern portion ESR-2 spaced apart from each other with the transmission portion TMA therebetween. The first pattern portion ESR-1 may be in contact with the first light-blocking portion BLA-1 and the second pattern portion ESR-2 may be in contact with the second light-blocking portion BLA-2. In the thickness direction DR3, the first pattern portion ESR-1 may be disposed on the second region B_A2 of the first light-blocking portion BLA-1. In the thickness direction DR3, the second pattern portion ESR-2 may be disposed on the fourth region B_A4 of the second light-blocking portion BLA-2. The first pattern portion ESR-1 and the second insulating layer IS-L2 of the input-sensing layer ISP may be spaced apart from each other with the second region B_A2 of the first light-blocking portion BLA-1 therebetween. The second pattern portion ESR-2 and the second insulating layer IS-L2 of the input-sensing layer ISP may be spaced apart from each other with the fourth region B_A4 of the second light-blocking portion BLA-2 therebetween.

In the fourth direction DR4, a width W3 of the first pattern portion ESR-1 may be substantially the same as a width W1 of the second region B_A2 of the first light-blocking portion BLA-1. In the fourth direction DR4, a width W4 of the second pattern portion ESR-2 may be substantially the same as a width W2 of the fourth region B_A4 of the second light-blocking portion BLA-2. In the present disclosure, the wording, “being substantially the same as” includes not only a case of having the physically same numerical values, but also a case of having a difference within a range of error that may generally occur in a process.

In a later-described method of manufacturing a display device according to some embodiments, the light-blocking portion BLA may be formed by filling a space between the transmission portion TMA and the pattern portion ESR. Accordingly, the width W3 of the first pattern portion ESR-1 may be substantially the same as the width W1 of the second region B_A2 of the first light-blocking portion BLA-1, and the width W4 of the second pattern portion ESR-2 may be substantially the same as the width W2 of the fourth region B_A4 of the second light-blocking portion BLA-2.

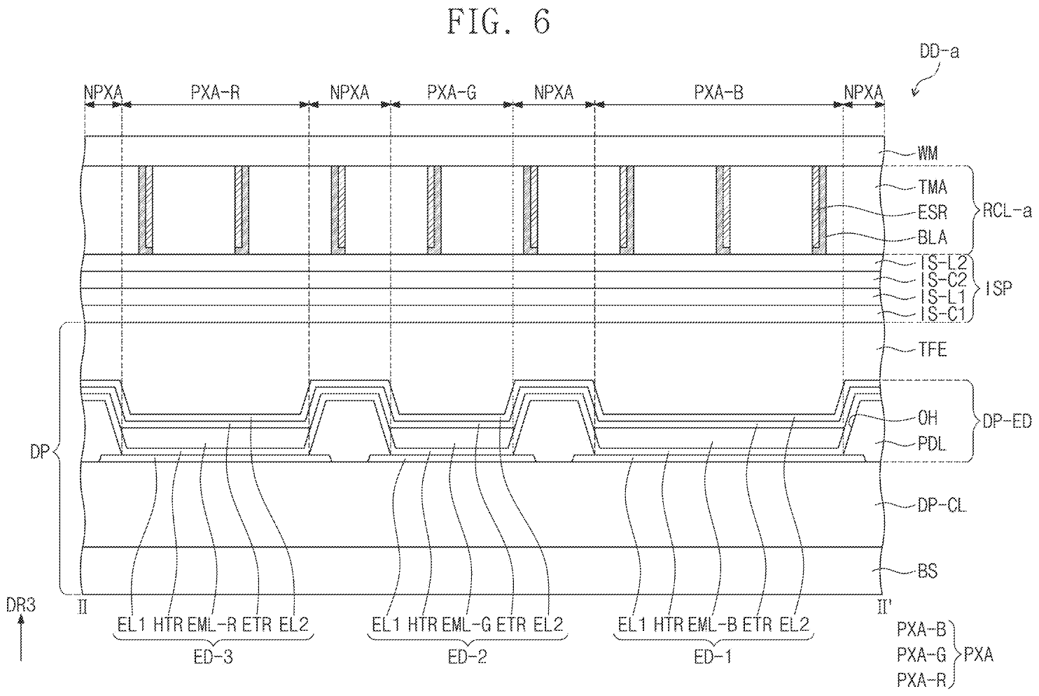

FIG. 6 is a cross-sectional view illustrating other embodiments of the present disclosure. Hereinafter, the description of FIG. 6 will primarily focus on the differences with the embodiments of FIGS. 1-5, and the description of common elements may be omitted for brevity purposes.

Compared with the display device DD illustrated in FIG. 4, a display device DD-a in FIG. 6 has a difference in a light control layer RCL-a. The light control layer RCL-a illustrated in FIG. 6 is different from the light control layer RCL illustrated in FIG. 4 in that the auxiliary transmission portion TMA-S (see, e.g., FIG. 5) is not included. The light control layer RCL-a may include a light-blocking portion BLA, a pattern portion ESR, and a transmission portion TMA. A window member WM may be disposed on the light-blocking portion BLA, the pattern portion ESR, and the transmission portion TMA. The light control layer RCL-a may include the light-blocking portion BLA having a relatively small width and the transmission portion TMA having a relatively great width (e.g., large width), and thus, may exhibit excellent light transmittance. In addition, the display device DD-a including the light control layer RCL-a may exhibit excellent display quality.

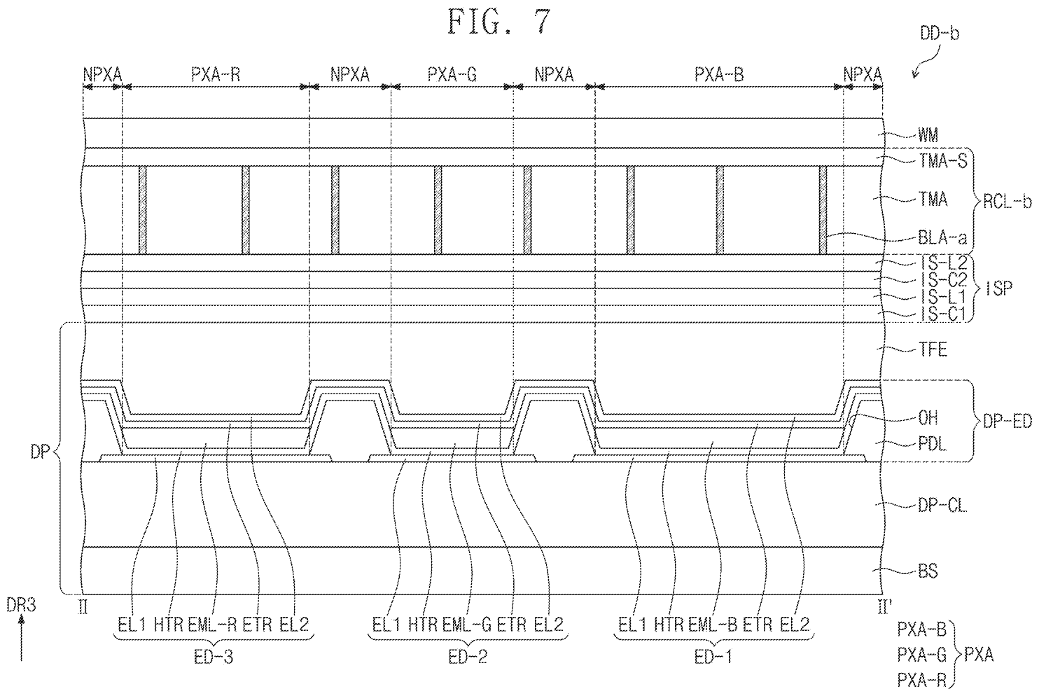

FIG. 7 is a cross-sectional view illustrating other embodiments of the present disclosure. Hereinafter, the description of FIG. 7 will primarily focus on the differences with the embodiments of FIGS. 1-6, and the description of common elements may be omitted for brevity purposes.

Compared with the display device DD illustrated in FIG. 4, a display device DD-b in FIG. 7 has a difference in a light control layer RCL-b. The light control layer RCL-b illustrated in FIG. 7 is different from the light control layer RCL illustrated in FIG. 4 in that the pattern portion ESR (see, e.g., FIG. 5) is not included. In addition, a light-blocking portion BLA-a illustrated in FIG. 7 is different from the light-blocking portions BLA illustrated in FIGS. 4 and 5 in that the second region B_A2 (see, e.g., FIG. 5) and the fourth region B_A4 (see, e.g., FIG. 5) are not included. That is, the light-blocking portion BLA-a may include only the first region B_A1 (see, e.g., FIG. 5) and the third region B_A3 (see, e.g., FIG. 5) extending in a direction parallel to the thickness direction DR3.

The light control layer RCL-b may include a light-blocking portion BLA, a transmission portion TMA, and an auxiliary transmission portion TMA-S. A window member WM may be disposed on the auxiliary transmission portion TMA-S. Unlike what is illustrated in FIG. 6, the auxiliary transmission portion TMA-S may be omitted. The light control layer RCL-b may include the light-blocking portion BLA having a relatively small width and the transmission portion TMA having a relatively great width (e.g., large width), and thus, may exhibit excellent light transmittance. In addition, the display device DD-b including the light control layer RCL-b may exhibit excellent display quality.

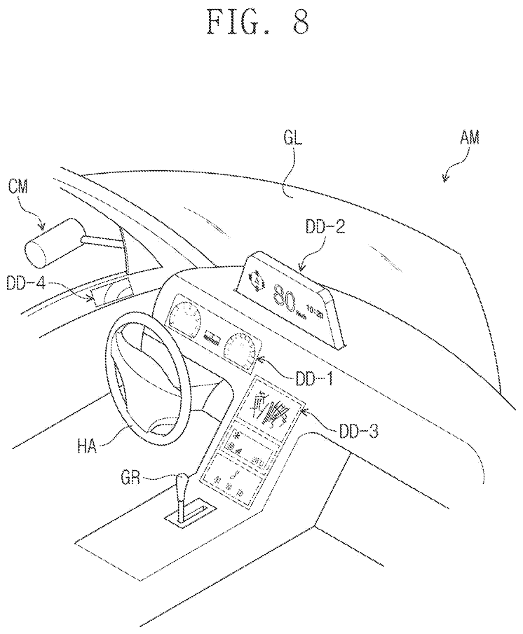

FIG. 8 is a diagram illustrating a vehicle AM in which first to fourth display devices DD-1, DD-2, DD-3, and DD-4 are disposed. At least one among the first to fourth display devices DD-1, DD-2, DD-3, and DD-4 may have the same configuration as one of the display devices DD, DD-a, and DD-b according to the foregoing embodiments described with reference to FIGS. 1 to 7.

FIG. 8 illustrates a car as the vehicle AM; however, this is merely an example. The first to fourth display devices DD-1, DD-2, DD-3, and DD-4 may be disposed in another transportation means such as a bicycle, a motorcycle, a train, a boat, and an airplane. These are merely presented as examples, and at least one among the first to fourth display devices DD-1, DD-2, DD-3, and DD-4 may be a display device employed in another electronic apparatus without departing from the idea of the present disclosure.

At least one among the first to fourth display devices DD-1, DD-2, DD-3, and DD-4 may include one of the light control layers RCL, RCL-a, and RCL-b according to the foregoing embodiments described with reference to FIGS. 4 to 7. At least one among the first to fourth display devices DD-1, DD-2, DD-3, and DD-4 may include one of the light control layers RCL, RCL-a, and RCL-b according to the embodiments, thereby showing excellent display quality.

Referring to FIG. 8, the vehicle AM may include a steering wheel HA and a gear GR for operating the vehicle AM, and a front window GL facing a driver may be disposed.

A first display device DD-1 may be disposed in a first region overlapping (e.g., in a plan view) the steering wheel HA. For example, the first display device DD-1 may be a digital cluster that displays first information of the vehicle AM. The first information may include a first scale indicating a driving speed of the vehicle AM, a second scale indicating a number of revolutions of an engine (RPM (revolutions per minute)), an image indicating a fuel condition, and the like. The first scale and the second scale may be displayed as digital images.

A second display device DD-2 may be disposed in a second region facing a driver's seat and overlapping the front window GL. The driver's seat may be a seat in which the steering wheel HA is disposed. For example, the second display device DD-2 may be a head-up display (HUD) that displays second information of the vehicle AM. The second display device DD-2 may be optically transparent. The second information may include a digital number representing the driving speed of the vehicle AM, and may further include information such as current time. In some examples, unlike what is illustrated, the second information of the second display device DD-2 may be projected and displayed on the front window GL.

A third display device DD-3 may be disposed in a third region adjacent to the gear GR. For example, the third display device DD-3 may be a center information display (CID) which is disposed between the driver's seat and a passenger's seat, and displays third information. The passenger's seat may be a seat spaced apart from the driver's seat with the gear GR therebetween. The third information may include information related to street conditions (for example, navigation information), playing of music or a radio broadcast, reproduction of a dynamic video (or image), and an internal temperature of the vehicle AM.

A fourth display device DD-4 may be disposed in a fourth region spaced apart from the steering wheel HA and the gear GR, and adjacent to a side part of the vehicle AM. For example, the fourth display device DD-4 may be a digital side-view mirror that displays fourth information. The fourth display device DD-4 may display an external image of the vehicle AM captured by a camera module CM disposed outside of the vehicle AM. The fourth information may include the external image of the vehicle AM.

The positions of the first to fourth display devices DD-1, DD-2, DD-3, and DD-4 illustrated in FIG. 8 are exemplary illustrated, and may thus be changed to other positions in consideration of driver's convenience. In addition, the first to fourth information described above are examples, and the first to fourth display devices DD-1, DD-2, DD-3, and DD-4 may further display information pertaining to the inside and outside of the vehicle. The first to fourth information may include pieces of information different from each other. However, embodiments of the present disclosure are not limited thereto, and part of the first to fourth information may include information identical to each other.

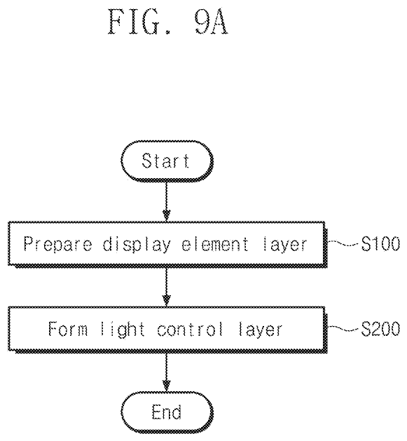

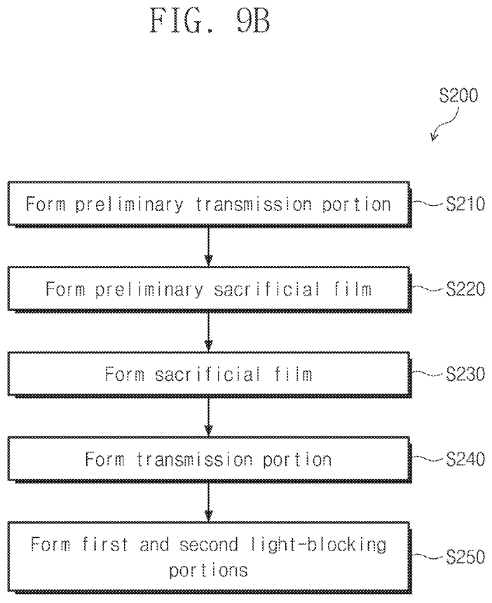

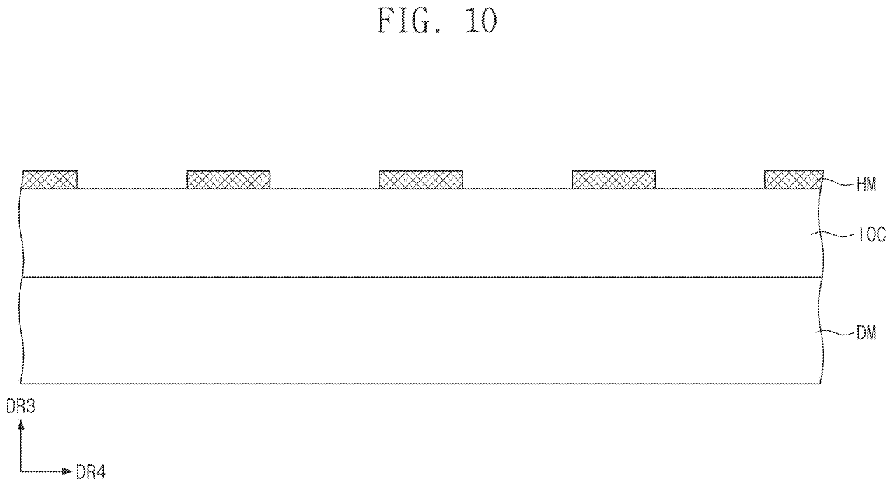

A display device according to some embodiments is manufactured by a method of manufacturing a display device according to some embodiments. FIGS. 9A and 9B are flowcharts illustrating the method of manufacturing a display device according to some embodiments. FIGS. 10 to 21 are diagrams schematically illustrating operations for manufacturing a display device according to some embodiments. Hereinafter, the description of FIGS. 9A to 21 will primarily focus on the differences with the embodiments of FIGS. 1-8, and the description of common elements may be omitted for brevity purposes.

Referring to FIG. 9A, the method of manufacturing a display device according to some embodiments includes an operation (S100) of preparing a display element layer, and an operation (S200) of forming a light control layer. Referring to FIG. 9B, the operation (S200) of forming the light control layer may include an operation (S210) of forming a preliminary transmission portion, an operation (S220) of forming a preliminary sacrificial film, an operation (S230) of forming a sacrificial film, an operation (S240) of forming a transmission portion, and an operation (S250) of forming first and second light-blocking portions.

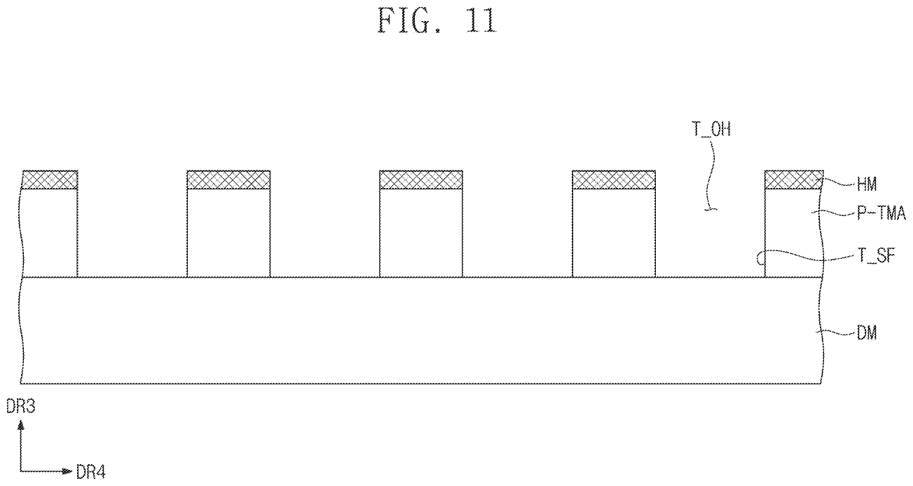

Referring to FIG. 10, a first organic material IOC may be provided on a display module DM. The first organic material IOC may be directly applied on an input-sensing layer ISP (see, e.g., FIG. 4) of the display module DM. Successively, a hard mask HM may be formed on the first organic material IOC. Referring to FIG. 11, a preliminary transmission portion P-TMA may be formed by patterning the first organic material IOC using the hard mask HM. An opening T_OH may be defined in the preliminary transmission portion P-TMA. The preliminary transmission portion P-TMA may include side surfaces T_SF defining the opening T_OH.

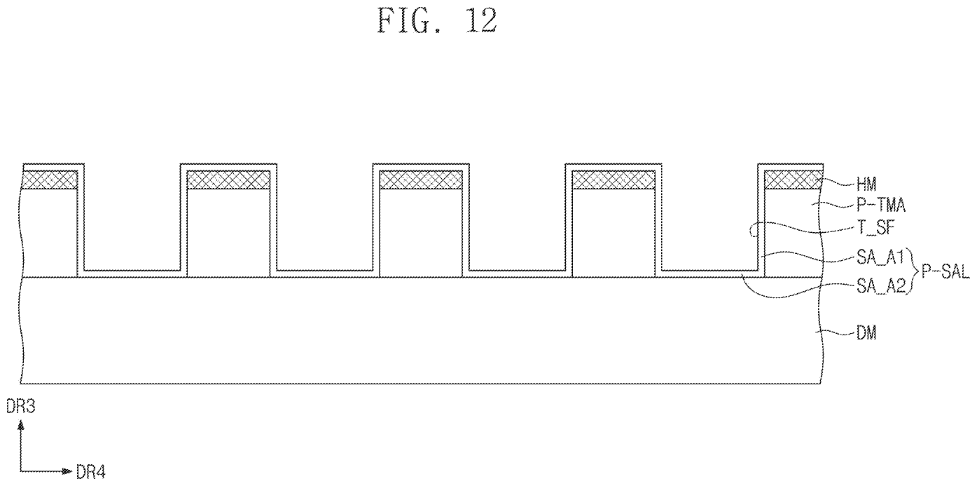

Referring to FIG. 12, a preliminary sacrificial film P-SAL may be formed on the preliminary transmission portion P-TMA. The preliminary sacrificial film P-SAL may be formed by depositing metal. For example, the preliminary sacrificial film P-SAL may include at least one of molybdenum (Mo) or aluminum (AI). However, this is merely an example, and metal included in the preliminary sacrificial film P-SAL may be used without limitation as long as being easily removed in later processes.

The preliminary sacrificial film P-SAL may be formed so as to cover the preliminary transmission portion P-TMA. The preliminary sacrificial film P-SAL may include a first portion SA_A1 and a second portion SA_A2. The first portion SA_A1 and the second portion SA_A2 may have an integrated shape. The second portion SA_A2 may cross the first portion SA_A1. For example, the first portion SA_A1 may extend in a direction parallel to the thickness direction DR3, and the second portion SA_A2 may extend in a direction parallel to the fourth direction DR4. The first portion SA_A1 may be formed on the side surfaces T_SF of the preliminary transmission portion P-TMA.

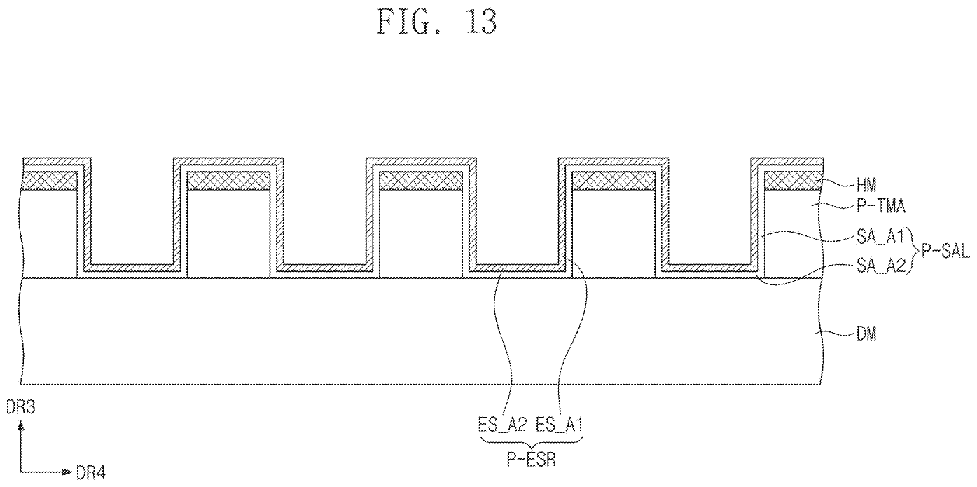

Referring to FIG. 13, a preliminary pattern portion P-ESR may be formed on the preliminary sacrificial film P-SAL. The preliminary pattern portion P-ESR may include a third portion ES_A1 and a fourth portion ES_A2. The third portion ES_A1 and the fourth portion ES_A2 may have an integrated shape. The fourth portion ES_A2 may cross the third portion ES_A1. The third portion ES_A1 may extend in a direction parallel to the thickness direction DR3, and the fourth portion ES_A2 may extend in a direction parallel to the fourth direction DR4.

The preliminary pattern portion P-ESR may be directly formed on the preliminary sacrificial film P-SAL. The preliminary pattern portion P-ESR may entirely overlap the preliminary sacrificial film P-SAL (e.g., in a plan view). The third portion ES_A1 of the preliminary pattern portion P-ESR may be disposed on the first portion SA_A1 of the preliminary sacrificial film P-SAL. The fourth portion ES_A2 of the preliminary pattern portion P-ESR may be disposed on the second portion SA_A2 of the preliminary sacrificial film P-SAL.

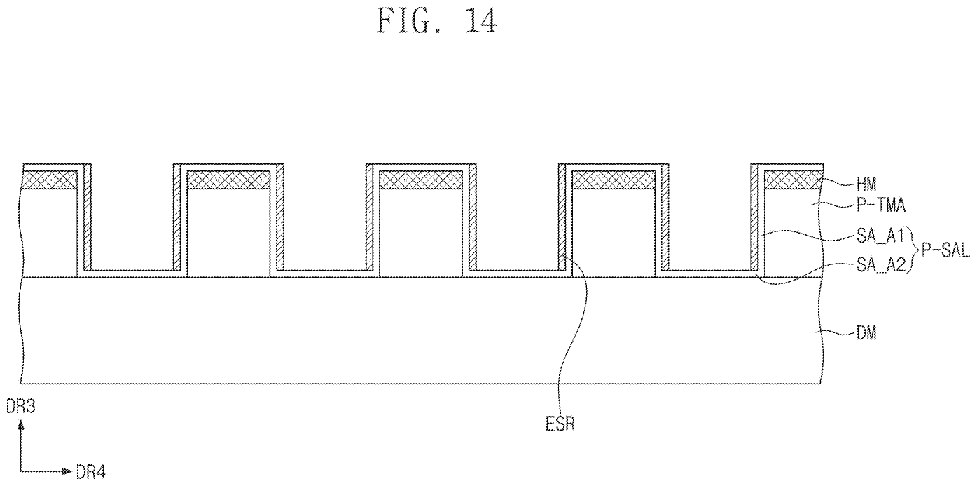

Referring to FIG. 14, the pattern portion ESR may be formed by removing the fourth portion ES_A2 of the preliminary pattern portion P-ESR. The fourth portion ES_A2 extending from the preliminary pattern portion P-ESR in the fourth direction DR4 perpendicular to the thickness direction DR3 may be removed. In the preliminary pattern portion P-ESR, the third portion ES_A1 may remain, and the fourth portion ES_A2 may be removed by anisotropic etching. For example, when the preliminary pattern portion P-ESR is formed of an insulating material, the preliminary pattern portion P-ESR may be etched by providing fluorine gas, argon gas, carbon, and/or the like. However, this is merely an example, and a material provided to etch the preliminary pattern portion P-ESR is not limited thereto.

Referring to FIG. 15, a plurality of sacrificial films SAL may be formed by removing a part of the second portion SA_A2 of the preliminary sacrificial film P-SAL. The sacrificial films SAL may be formed on the side surfaces T_SF of the preliminary transmission portion P-TMA.

A part of the second portion SA_A2 of the preliminary sacrificial film P-SAL may be removed by dry etching. For example, a part of the second portion SA_A2 of the preliminary sacrificial film P-SAL may be removed by anisotropic etching. A part of the second portion SA_A2 may not overlap (e.g., in a plan view) the pattern portion ESR. That is, in the preliminary sacrificial film P-SAL, a part, of the second portion SA_A2, not overlapping the pattern portion ESR may be removed. The pattern portion ESR may serve as an etch stopper for the first portion SA_A1 of the preliminary sacrificial film P-SAL.

The sacrificial film SAL may include a first sacrificial film SAL-1 and a second sacrificial film SAL-2. The first sacrificial film SAL-1 and the second sacrificial film SAL-2 may each be in contact with the pattern portion ESR. When a part of the second portion SA_A2 of the preliminary sacrificial film P-SAL is removed, the hard mask HM formed on the preliminary transmission portion P-TMA may be removed.

The first sacrificial film SAL-1 may include a first sacrificial region SA_A11 and a second sacrificial region SA_A21. The second sacrificial film SAL-2 may include a third sacrificial region SA_A12 and a fourth sacrificial region SA_A22.

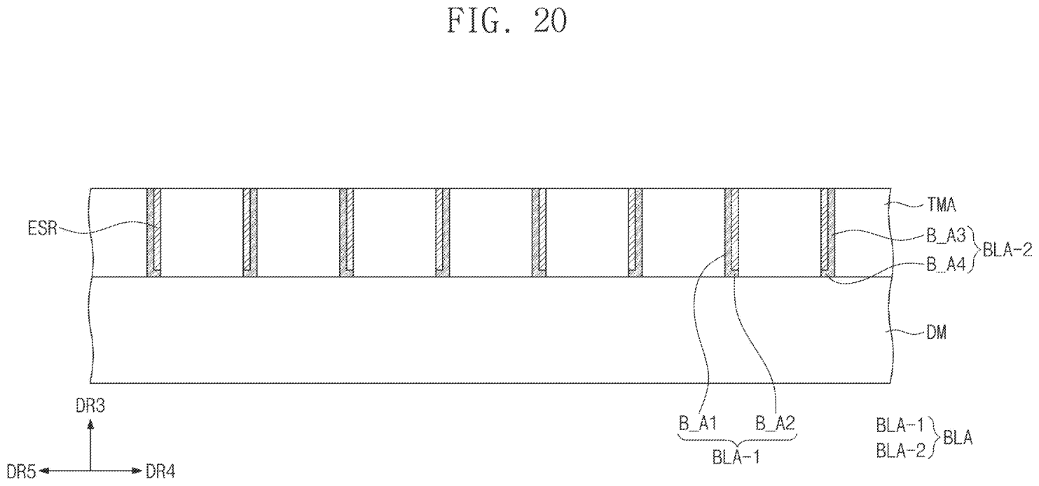

The first sacrificial region SA_A11 and the third sacrificial region SA_A12 may be formed from the first portion SA_A1 (see, e.g., FIG. 14) of the preliminary sacrificial film P-SAL (see, e.g., FIG. 14). The first sacrificial region SA_A11 and the third sacrificial region SA_A12 may extend parallel to the thickness direction DR3. The second sacrificial region SA_A21 and the fourth sacrificial region SA_A22 may be formed by removing a part of the second portion SA_A2 of the preliminary sacrificial film P-SAL (see, e.g., FIG. 14). The second sacrificial region SA_A21 may extend in the fourth direction DR4, and the fourth sacrificial region SA_A22 may extend in the fifth direction DR5. In an operation to be performed later, the light-blocking portion BLA (see, e.g., FIG. 20) may be formed by removing the sacrificial film SAL. The light-blocking portion BLA (see, e.g., FIG. 20) formed by removing the sacrificial film SAL including the first to fourth sacrificial regions SA_A11, SA_A21, SA_A12, and SA_A22 may include the first to fourth regions B_A1, B_A2, B_A3, and B_A4 (see, e.g., FIG. 20). The first to fourth regions B_A1, B_A2, B_A3, and B_A4 (see, e.g., FIG. 20) may correspond to the first to fourth sacrificial regions SA_A11, SA_A21, SA_A12, and SA_A22. An operation of forming the light-blocking portion BLA will be described in more detail later.

Referring to FIGS. 15 to 17, the transmission portion TMA may be formed by providing a second organic material filling the opening T_OH of the preliminary transmission portion P-TMA. The second organic material filling the opening T_OH may be the same or substantially the same material as the first organic material IOC provided to form the preliminary transmission portion P-TMA.

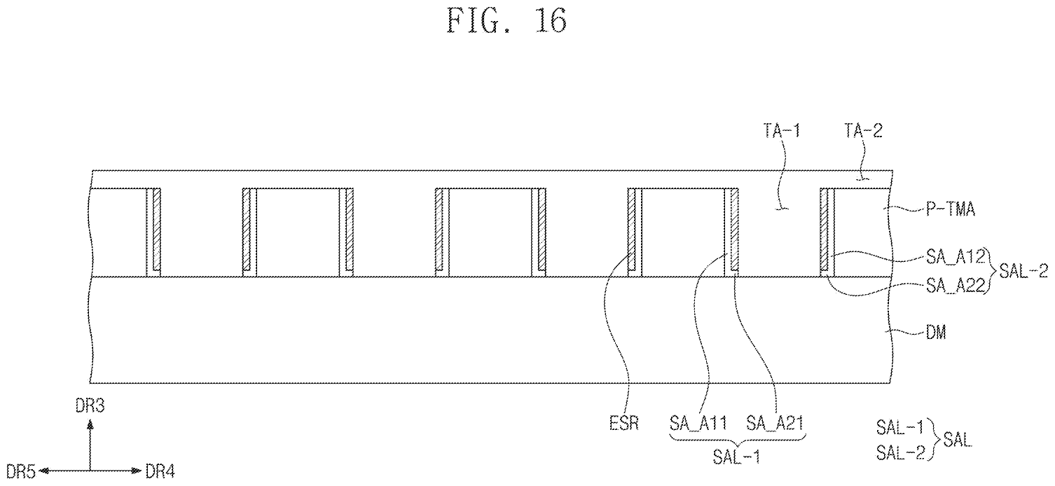

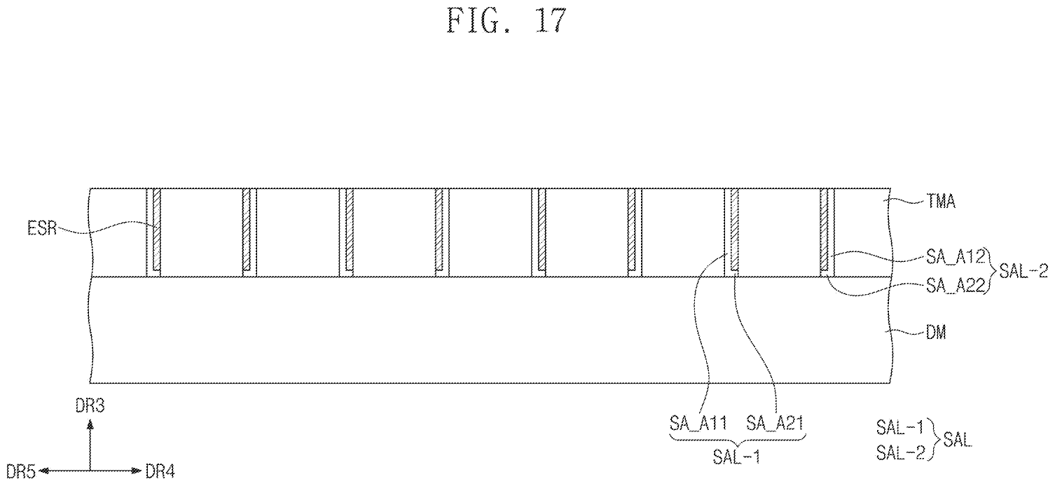

Referring to FIG. 16, the second organic material may be applied onto the entire surface. A first preliminary transmission region TA-1 and a second preliminary transmission region TA-2 may be formed as a result of providing the second organic material. The first preliminary transmission region TA-1 may be formed by filling the opening T_OH, and the second preliminary transmission region TA-2 may be formed on the first preliminary transmission region TA-1 and the preliminary transmission portion P-TMA. Referring to FIG. 17, the second preliminary transmission region TA-2 may be removed by an ashing process.

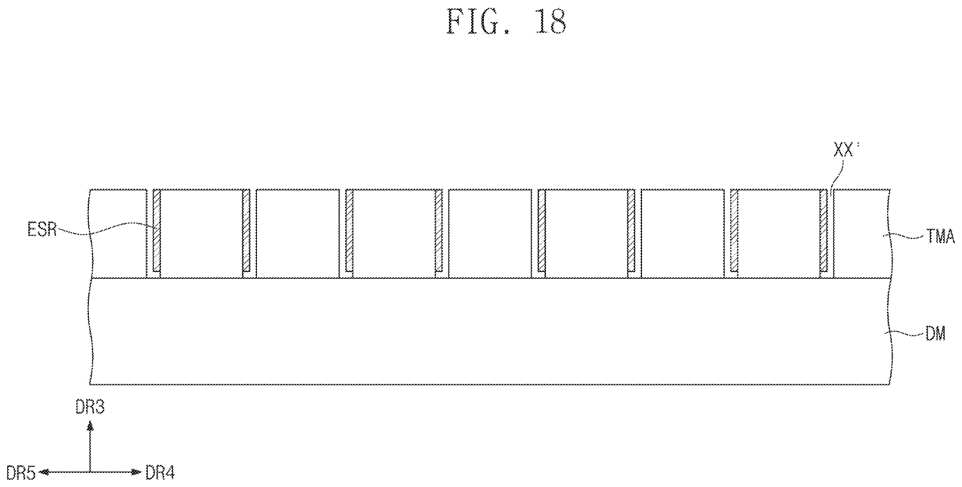

Referring to FIGS. 18 to 20, the light-blocking portion BLA may be formed by removing the sacrificial film SAL and filling a region XX′ in which the sacrificial film SAL is removed. Referring to FIG. 18, the sacrificial film SAL may be removed by wet etching. For example, the sacrificial film SAL may be removed by an etching solution including at least one of phosphoric acid, nitric acid, or acetic acid. However, this is merely an example, and the solution that etches the sacrificial film SAL is not limited thereto.

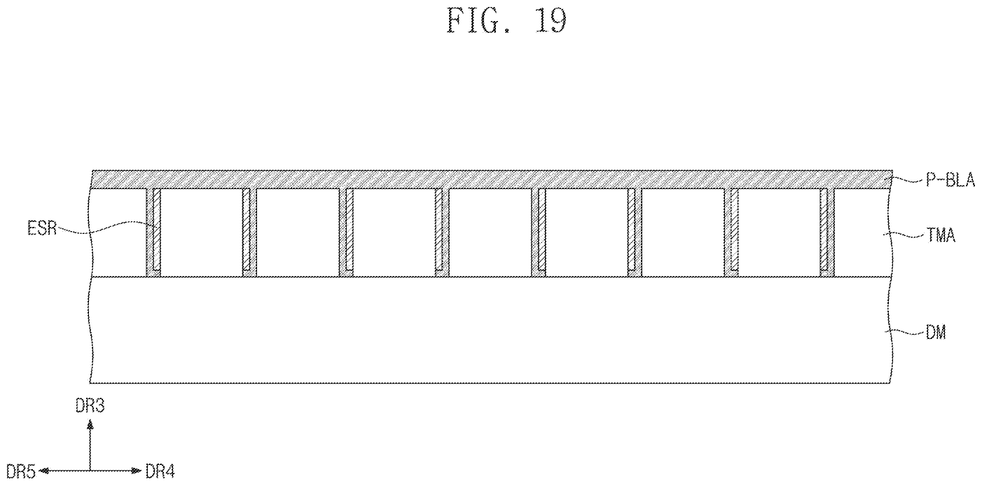

Referring to FIG. 19, a preliminary light-blocking portion P-BLA may be formed by filling the region XX′ in which the sacrificial film SAL is removed. The preliminary light-blocking portion P-BLA may be formed on the transmission portion TMA and the pattern portion ESR by filling the region XX′ in which the sacrificial film SAL is removed. Referring to FIG. 20, the light-blocking portion BLA may be formed by removing one region formed on the transmission portion TMA and the pattern portion ESR of the preliminary light-blocking portion P-BLA. The one region of the preliminary light-blocking portion P-BLA may be removed by an ashing process.

The light-blocking portion BLA formed in the region XX′ in which the sacrificial film SAL is removed may include the first to fourth regions B_A1, B_A2, B_A3, and B_A4. The light-blocking portion BLA may be formed by removing the sacrificial film SAL including the first to fourth sacrificial regions SA_A11, SA_A21, SA_A12, and SA_A22, and thus, may include the first to fourth regions B_A1, B_A2, B_A3, and B_A4 respectively corresponding to the first to fourth sacrificial regions SA_A11, SA_A21, SA_A12, and SA_A22.

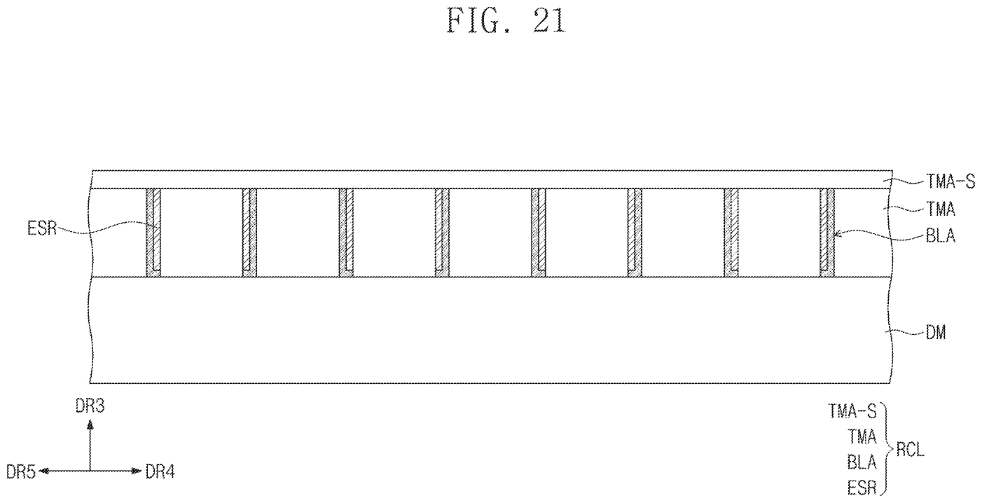

Referring to FIG. 21, the method of manufacturing a display device according to some embodiments further includes an operation of forming an auxiliary transmission portion TMA-S. The auxiliary transmission portion TMA-S may be formed on the light-blocking portion BLA, the pattern portion ESR, and the transmission portion TMA. The auxiliary transmission portion TMA-S may be formed by applying the same organic material as the transmission portion TMA.

Unlike what is illustrated, in the method of manufacturing a display device according to some embodiments, an operation of forming the preliminary pattern portion P-ESR and the pattern portion ESR may be omitted. When a display device is manufactured by a method of manufacturing a display device in which the operation of forming the preliminary pattern portion P-ESR and the pattern portion ESR is omitted, the display device DD-b illustrated in FIG. 7 may be formed.

In the method of manufacturing a display device according to some embodiments, the operation of forming a light control layer includes an operation of forming a sacrificial film, and an operation of removing the sacrificial film and forming a light-blocking portion in a region in which the sacrificial film is removed. Accordingly, a light-blocking portion having a relatively small width in one direction perpendicular to a thickness direction may be formed. Since the width of the light-blocking portion gets smaller with respect to the total width of the light control layer, the width of the transmission portion becomes greater, and therefore light transmittance of the light control layer may be improved. For example, the light-blocking portion formed by the method of manufacturing a display device according to some embodiments has a width of about 1 μm or less.

A typical light control layer includes only light-blocking portions and transmission portions. The light-blocking portions are formed by forming the transmission portions and filling a space between the transmission portions, and in this case, it is difficult for the light-blocking portions to be formed to have a width of less than about 2 μm. Since a light-blocking material forming the light-blocking portions has a lower strength than an organic material forming the transmission portions, the light-blocking material is easily damaged even by a slight external force, so that the light-blocking portion is formed to have a relatively great width (e.g., large width). In addition, as the light-blocking portion gets thicker due to the poorer strength of the light-blocking material, it is more difficult to form a light-blocking portion having a smaller width. In the light control layer, as the light-blocking portion has a greater width, the transmission portion has a smaller width, thereby resulting in deterioration of light transmittance and display quality.

Unlike the above, since the method of manufacturing a display device according to some embodiments includes an operation of forming a metal-containing sacrificial film and an operation of removing the sacrificial film and forming the light-blocking portion in a region which the sacrificial film is removed, the light-blocking portion having a relatively small width may be formed. Accordingly, the method of manufacturing a display device according to some embodiments shows excellent manufacturing reliability and manufacturing efficiency. In addition, a display device according to some embodiments formed by the method of manufacturing a display device according to some embodiments includes the light control layer including the light-blocking portion having a relatively small width, thereby improving light transmittance and showing excellent display quality.

Since a display device according to some embodiments manufactured by a method of manufacturing a display device according to some embodiments includes a light control layer having excellent light transmittance, the display device may exhibit excellent display quality.

The method of manufacturing a display device according to some embodiments includes an operation of forming a light-blocking portion in a region in which a sacrificial film is removed, thereby forming a light control layer having excellent light transmittance.

It will be understood that, although the terms “first”, “second”, “third”, etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section discussed below could be termed a second element, component, region, layer or section, without departing from the spirit and scope of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. In addition, it will also be understood that when a layer is referred to as being “between” two layers, it can be the only layer between the two layers, or one or more intervening layers may also be present.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” “comprising,” “has,” “have,” and “having,” when used in this specification, specify the presence of stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items. For example, the expression “A and/or B” denotes A, B, or A and B. Expressions such as “one or more of” and “at least one of,” when preceding a list of elements, modify the entire list of elements and do not modify the individual elements of the list. For example, the expression “one or more of A, B, and C,” “at least one of A, B, or C,” “at least one of A, B, and C,” and “at least one selected from the group consisting of A, B, and C” indicates only A, only B, only C, both A and B, both A and C, both B and C, or all of A, B, and C.

Further, the use of “may” when describing embodiments of the inventive concept refers to “one or more embodiments of the inventive concept.” Also, the term “exemplary” is intended to refer to an example or illustration.

It will be understood that when an element or layer is referred to as being “on”, “connected to”, “coupled to”, or “adjacent” another element or layer, it can be directly on, connected to, coupled to, or adjacent the other element or layer, or one or more intervening elements or layers may be present. When an element or layer is referred to as being “directly on,” “directly connected to”, “directly coupled to”, “in contact with”, “in direct contact with”, or “immediately adjacent” another element or layer, there are no intervening elements or layers present.

As used herein, the term “substantially,” “about,” and similar terms are used as terms of approximation and not as terms of degree, and are intended to account for the inherent variations in measured or calculated values that would be recognized by those of ordinary skill in the art.

As used herein, the terms “use,” “using,” and “used” may be considered synonymous with the terms “utilize,” “utilizing,” and “utilized,” respectively.

In the above, description has been made with reference to preferred embodiments of the present disclosure, but those skilled in the art or those of ordinary skill in the relevant technical field may understand that various suitable modifications and changes may be made to the inventive concept within the scope not departing from the spirit and the technological scope of the inventive concept, as defined by the claims and equivalents thereof.

What is claimed is:

1. A display device comprising:
a display element layer comprising a light-emitting element and a pixel-defining film; and
a light control layer on the display element layer, and comprising a first light-blocking portion, a second light-blocking portion spaced apart from the first light-blocking portion in one direction perpendicular to a thickness direction, and a transmission portion between the first light-blocking portion and the second light-blocking portion,
wherein the first light-blocking portion comprises a first region, and a second region extending from the first region, and crossing the first region, and
wherein the second light-blocking portion comprises a third region parallel to the first region, and a fourth region extending from the third region in a direction opposite to the second region.

2. The display device of claim 1, wherein the first region and the third region each extend in a direction parallel to the thickness direction.

3. The display device of claim 1, wherein the light control layer further comprises a first pattern portion and a second pattern portion spaced apart from each other with the transmission portion therebetween.

4. The display device of claim 3, wherein the first pattern portion is in contact with the first light-blocking portion, and the second pattern portion is in contact with the second light-blocking portion.

5. The display device of claim 3, wherein the first pattern portion is on the second region, and the second pattern portion is on the fourth region.

6. The display device of claim 3, wherein in the one direction, a width of the first pattern portion is equal to a width of the second pattern portion.

7. The display device of claim 3, wherein in the one direction, a width of the second pattern portion is equal to a width of the fourth region.

8. The display device of claim 1, wherein the light control layer further comprises an auxiliary transmission portion on the first light-blocking portion, the second light-blocking portion, and the transmission portion.

9. A method of manufacturing a display device, the method comprising:
preparing a display element layer comprising a light-emitting element and a pixel-defining film; and
forming, on the display element layer, a light control layer comprising a first light-blocking portion, a second light-blocking portion, and a transmission portion between the first light-blocking portion and the second light-blocking portion, the forming of the light control layer comprising:
forming a preliminary transmission portion having an opening defined therein by providing a first organic material onto the display element layer;
forming a preliminary sacrificial film covering the preliminary transmission portion;
forming a plurality of sacrificial films by removing, from the preliminary sacrificial film, a first portion extending in a first direction crossing a thickness direction;
forming the transmission portion from the preliminary transmission portion by filling the opening with a second organic material; and
removing the sacrificial films, and forming the first light-blocking portion and the second light-blocking portion that fill regions in which the sacrificial films are removed.

10. The method of claim 9, further comprising, between the forming of the preliminary sacrificial film and the forming of the plurality of sacrificial films:
forming a preliminary pattern portion on the preliminary sacrificial film; and
forming a pattern portion by removing, from the preliminary pattern portion, a second portion extending in the first direction.

11. The method of claim 10, wherein the preliminary pattern portion entirely overlaps the preliminary sacrificial film.

12. The method of claim 9, wherein the preliminary sacrificial film is formed by depositing metal.

13. The method of claim 9, wherein in the forming of the plurality of sacrificial films, the first portion is removed by anisotropic etching.

14. The method of claim 9, wherein the sacrificial films are formed on a side surface of the preliminary transmission portion defining the opening.

15. The method of claim 9, wherein in the forming of the first light-blocking portion and the second light-blocking portion, the sacrificial films are removed by wet etching.

16. The method of claim 9, wherein the forming of the transmission portion comprises:
forming a first preliminary transmission region and a second preliminary transmission region by providing the first organic material; and
forming the transmission portion by removing the second preliminary transmission region,
wherein the first preliminary transmission region is formed by filling the opening, and
wherein the second preliminary transmission region is formed on the preliminary transmission portion and the first preliminary transmission region.

17. The method of claim 16, wherein the second preliminary transmission region is removed by an ashing process.

18. The method of claim 9, further comprising, after the forming of the first light-blocking portion and the second light-blocking portion:
forming an auxiliary transmission portion on the first light-blocking portion, the second light-blocking portion, and the transmission portion.

19. The method of claim 9, wherein the forming of the preliminary transmission portion comprises:
providing the first organic material on the display element layer; and
forming the preliminary transmission portion by patterning the first organic material using a hard mask.

20. The method of claim 19, wherein in the removing of the first portion, the hard mask is removed.
